(19) United States
(12) Patent Application Publication
(10) Pub. No.: US 2023/0295789 A1
(43) Pub. Date: Sep. 21, 2023

(54) DENSE VERTICALLY SEGMENTED SILICON COATING FOR LOW DEFECTIVITY IN HIGH-TEMPERATURE RAPID THERMAL PROCESSING

(71) Applicant: Applied Materials, Inc., Santa Clara, CA (US)

(72) Inventors: David JORGENSEN, Moutain View, CA (US); Jian WU, San Jose, CA (US); Abhilash J. MAYUR, Salinas, CA (US)

(21) Appl. No.: 17/695,475

(22) Filed: Mar. 15, 2022

(51) Int. Cl. C23C 4/134; C23C 4/04

(52) U.S. Cl. CPC C23C 4/134; C23C 4/04

(57) ABSTRACT

This application generally relates to a chamber component for a thermal processing chamber comprising a base component having a coating disposed thereon, the coating having a base component having a coating disposed thereon, the coating includes a surface, a thickness, and a plurality of cracks extending from the surface of the coating through at least 40 percent of the thickness of the coating.

### BACKGROUND

### Field

The present disclosure relates generally to components used in processing a substrate, such as in semiconductor processing applications, and methods for forming a coating on the components. Specifically, the present invention relates to an air plasma spray silicon coating formed on processing chamber components to prevent hairline fracture growth and formation, and methods of forming the coating.

### Description of the Related Art

Plasma spraying is a coating process in which powders of coating materials are fed into a plasma jet. A plasma-spraying torch generates the plasma within a high-velocity flowing gas stream. The plasma melts the powders and sprays the coating materials over the target. Upon impact, the molten particles cool down and solidify instantly coating the target material.

Many components of processing chambers are coated for protection in high temperature processing environments. However, coating materials applied by typical air plasma spray (APS) silicon coatings cannot experience large thermal gradients without sustaining coating damage. Because APS silicon coatings have low in-plane compliance, they are susceptible to fracture when used at high temperatures under large thermal transient stresses. Thermal stress relaxation and thermal contraction of silicon coatings causes existing hairline cracks to grow, and new cracks to form in the coating during rapid thermal processing (RTP). The growth of existing cracks and formation of new cracks releases particles from the coated components within a processing volume of a processing chamber, such as an RTP chamber, that cause defects on substrates being processed in the chamber. Moreover, as the silicon coating is exposed to repeated thermal cycles during substrate processing over time, the existing cracks continue to grow, and new cracks continue to form, creating a never-ending cycle of new particles released into the processing volume of the processing chamber.

Furthermore, simply polishing the coating to remove the new particles does not solve the problem, as new cracks continue to form even when the previous coating layer is polished. Thus, there is a need to form a silicon APS coating for components used in processing chambers that reduces the likelihood of particle defects on the substrate being processed when used in high-temperature and thermally transient applications.

### SUMMARY

In one embodiment, a chamber component for a thermal processing chamber is provided. The chamber component includes a base component having a coating disposed thereon. The coating includes a surface, a thickness, and a plurality of cracks extending from the surface of the coating through at least 40 percent of the thickness of the coating.

In another embodiment, a support ring for use in a thermal processing chamber is provided. The support ring having a coating disposed thereon. The coating includes a surface, a thickness, and a plurality of cracks extending from the surface of the coating through at least 40 percent of the thickness of the coating, wherein the average spacing between the plurality of cracks is between 70 µm and 125 µm.

In yet another embodiment, a thermal processing chamber is provided. The thermal processing chamber includes a chamber body comprising a base, one or more side walls, and a lid enclosing a processing volume. The thermal processing chamber further includes a substrate support comprising a support cylinder, a support ring, and an edge ring disposed within the processing volume. The support ring has a coating disposed thereon. The coating includes a surface, a thickness, and a plurality of cracks extending from the surface of the coating through at least 40 percent of the thickness of the coating.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a simplified isometric view of a process chamber, according to one embodiment.

FIG. 2 is a cross-section of a support ring with an air plasma spray (APS) silicon coating, according to one embodiment.

FIG. 3 is a cross-sectional view of the APS silicon coating, according to one embodiment.

FIG. 4 is an illustration of a chart of comparing various fracture depths in the APS silicon coating, according to one embodiment.

### DETAILED DESCRIPTION

In the following description, numerous specific details are set forth to provide a more thorough understanding of the present invention. However, it will be apparent to one of skill in the art that the present invention may be practiced without one or more of these specific details. In other instances, well-known features have not been described in order to avoid obscuring the present invention.

As a typical air plasma spray (APS) silicon coating formed on a substrate processing chamber component, such as a rapid thermal processing (RTP) chamber component, is exposed to repeated heat cycles, the silicon coating begins to crack to release tensile stress across the coating. The growth of existing cracks and formation of new cracks in the APS silicon coating releases particles that cause particle defects on a substrate during processing. The cracks typically start at a higher temperature location within the RTP chamber. The crack starts and propagates along the coated component. As the coated component is exposed to additional thermal cycles, the existing crack continues to grow, and new cracks continue to form, creating a never-ending cycle of new particles released into the processing volume of the RTP chamber.

To solve the above-described problems, the present disclosure provides an APS silicon coating that can be formed on chamber components, having large, pre-existing cracks formed through the thickness of the APS silicon coating to relieve thermal strain during processing. The inventors have found that by forming the APS coating with a pre-cracked configuration on the chamber components, new cracks are prevented from forming in the coating during typical thermal operation of processing substrates, such as in the RTP chamber.

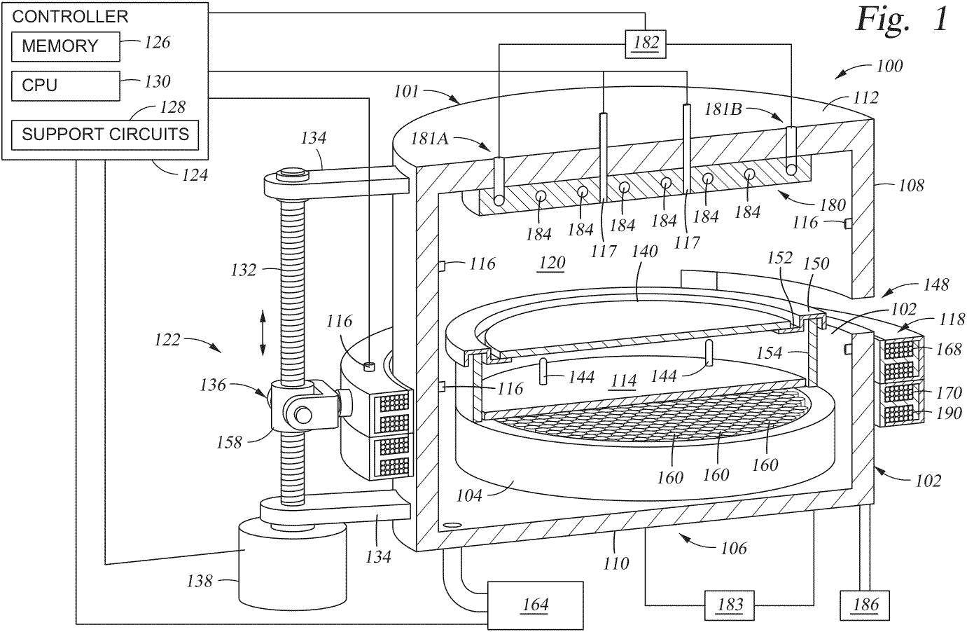

FIG. 1 is a simplified isometric view of one embodiment of a rapid thermal processing system 100. The rapid thermal processing system 100 includes a processing chamber 101, a stator assembly 118, an atmosphere control system 164, and a controller 124. The processing chamber 101 includes a chamber body 102 comprising walls 108, a bottom 110, and a top 112. The walls 108, bottom 110, and top 112 define an interior volume 120. The walls 108 typically include at least one substrate access port 148 to facilitate entry and egress of a substrate 140 (a portion of which is shown in FIG. 1). In some configurations the access port is coupled to a transfer chamber (not shown) or a load lock chamber (not shown) and can be selectively sealed with a valve.

Examples of rapid thermal processing chambers that may be adapted to benefit from the disclosure are Centura RadOx, Radiance, RadOx 2, and Vulcan thermal processing systems. The rapid thermal processing chambers are available from Applied Materials, Inc., located in Santa Clara, CA. Embodiments described herein can also be utilized in other processing systems and devices where high temperature processing is desired. Examples of other processing systems include substrate support platforms adapted for robot handoffs, orientation device, deposition chambers, etch chambers, electrochemical processing apparatuses and chemical mechanical polishing devices, among others, particularly where the minimization of particulate generation is desired.

Disposed within the interior volume 120 are a substrate support 104, a window 114, a radiant heat source 106, and a cooling block 180. In some configurations, the radiant heat source 106 is disposed in an inside diameter of the substrate support 104. In one embodiment, the substrate support 104 is magnetically levitated. As shown, the substrate support 104 is annular, and includes a support cylinder 154, a support ring 150, and an edge ring 152. The support ring 150 rests on the support cylinder 154, and the edge ring 152 rests on, and is nested with, the support ring 150. The edge ring 152 has a substrate support surface for receiving a substrate for processing. In one embodiment, the edge ring comprises quartz, amorphous silica, or silicon carbide, and can be optionally coated with silicon carbide. In one embodiment, the support ring 150 comprises quartz, bubble quartz, amorphous quartz, or amorphous silica, and has a sol coating that blocks transmission of light from the radiant heat source 106.

The window 114 is typically made from a material transparent to heat and light of various wave-lengths, such as infra-red (IR) light, through which photons from the radiant heat source 106 heat the substrate 140. In one embodiment, the window 114 is made of a quartz material, although other materials that are transparent to light may be used, such as sapphire. In one configuration, the window 114 includes a plurality of lift pins 144 coupled to an upper surface of the window 114, which are adapted to selectively contact and support the substrate 140, to facilitate transfer of the substrate into and out of the process chamber 100. Each of the plurality of lift pins 144 are configured to minimize absorption of energy from the radiant heat source 106 and are made from the same material used for the window 114, such as a quartz material. The plurality of lift pins 144 are positioned and radially spaced from each other to facilitate passage of an end effector coupled to a transfer robot (not shown). The end effector and/or robot is capable of horizontal and vertical movement to facilitate transfer of the substrate 140.

The radiant heat source 106 includes a lamp assembly formed from a housing which includes a plurality of honeycomb-like tubes 160 in a coolant assembly (not shown) coupled to a coolant source 183. The coolant source 183 may be one or a combination of water, ethylene glycol, nitrogen (N₂), and helium (He). The housing may be made of a copper material or other suitable material having suitable coolant channels formed therein for flow of the coolant from the coolant source 183. Each honeycomb-like tube 160 may contain a reflector and a high-intensity lamp assembly or an IR emitter. The radiant heat source 106 may further comprise annular zones, wherein the voltage supplied to the plurality of honeycomb-like tubes 160 by the controller 124 may be varied to enhance the radial distribution of energy from the honeycomb-like tubes 160. Dynamic control of the heating of the substrate 140 may be effected by one or more temperature sensors 117 adapted to measure the temperature across the substrate 140.

The stator assembly 118 circumscribes the walls 108 of the chamber body 102 and is coupled to one or more actuator assemblies 122 that control the elevation of the stator assembly 118 along the exterior of the chamber body 102. The stator assembly 118 is magnetically coupled to the substrate support 104 disposed within the interior volume 120 of the chamber body 102. The substrate support 104 may include a magnetic portion to function as a rotor, thus creating a magnetic bearing assembly to lift and/or rotate the substrate support 104. In one embodiment, at least a portion of the substrate support 104 is partially surrounded by a trough (not shown) that is coupled to a fluid source 186, which may include water, ethylene glycol, nitrogen (N₂), helium (He), or combinations thereof, adapted as a heat exchange medium for the substrate support. The stator assembly 118 may also include a housing 190 to enclose various parts and components of the stator assembly 118. In one embodiment, the stator assembly 118 includes a drive coil assembly 168 stacked on a suspension coil assembly 170. The drive coil assembly 168 is adapted to rotate and/or raise/lower the substrate support 104 while the suspension coil assembly 170 may be adapted to passively center the substrate support 104 within the processing chamber 101. Alternatively, the rotational and centering functions may be performed by a stator having a single coil assembly.

The atmosphere control system 164 is also coupled to the interior volume 120 of the chamber body 102. The atmosphere control system 164 generally includes throttle valves and vacuum pumps for controlling chamber pressure. The atmosphere control system 164 may also be adapted to deliver process gases for thermal deposition processes.

The processing chamber 101 also includes the controller 124, which generally includes a central processing unit (CPU) 130, support circuits 128, and memory 126. The CPU 130 may be one of any form of computer processor that can be used in an industrial setting for controlling various actions and sub-processors. The memory 126, or computer-readable medium, may be one or more of readily available memory such as random access memory (RAM), read only memory (ROM), floppy disk, hard disk, or any other form of digital storage, local or remote, and is typically coupled to the CPU 130. The support circuits 128 are coupled to the CPU 130 for supporting the controller 124 in a conventional manner. These circuits include cache, power supplied, clock circuits, input/output circuitry, subsystems, and the like.

In one embodiment, each of the actuator assemblies 122 generally comprise a precision lead screw 132 coupled between two flanges 134 extending from the walls 108 of the chamber body 102. The lead screw 132 has a nut 158 that axially travels along the lead screw 132 as the screw rotates. A coupling 136 is coupled between the stator assembly 118 and nut 158 so that as the lead screw 132 to control the elevation of the stator assembly 118 at the interface with the coupling 136. Thus, as the lead screw 132 of one of the actuator assemblies 122 is rotated to produce relative displacement between the nuts 158 of the other actuator assemblies 122, the horizontal plane of the stator assembly 118 changes relative to a central axis of the chamber body 102.

In one embodiment, a motor 138, such as a stepper or servo motor, is coupled to the lead screw 132 to provide controllable rotation in response to a signal by the controller 124. Alternatively, other types of actuator assemblies 122 may be utilized to control the linear position of the stator assembly 118, such as pneumatic cylinders, hydraulic cylinders, ball screws, solenoids, linear actuators, and cam followers, among others.

The processing chamber 101 also includes one or more sensors 116, which are generally adapted to detect the elevation of the substrate support 104 (or substrate 140) within the interior volume 120 of the chamber body 102. The sensors 116 may be coupled to the chamber body 102 and/or other portions of the process chamber 100 and are adapted to provide an output indicative of the distance between the substrate support 104 and the top 112 and/or bottom 110 of the chamber body 102, and may also detect misalignment of the substrate support 104 and/or substrate 140.

The one or more sensors 116 are coupled to the controller 124 that receives the output metric from the sensors 116 and provides a signal or signals to the one or more actuator assemblies 122 to raise or lower at least a portion of the substrate support 104. The controller 124 may utilize a positional metric obtained from the sensors 116 to adjust the elevation of the stator assembly 118 at each actuator assembly 122 so that both the elevation and the planarity of the substrate support 104 and substrate 140 seated thereon may be adjusted relative to and a central axis of the process chamber 100 (e.g., a rapid thermal processing (RTP) chamber), and/or the radiant heat source 106. For example, the controller 124 may provide signals to raise the substrate support by actions of one actuator assembly 122 to correct axial misalignment of the substrate support 104, or the controller may provide a signal to all actuator assemblies 122 to facilitate simultaneous vertical movement of the substrate support 104.

The one or more sensors 116 may be ultrasonic, laser inductive, capacitive, or other type of sensor capable of detecting the proximity of the substrate support 104 within the chamber body 102. The sensors 116, may be coupled to the chamber body 102 proximate the top 112 or coupled to the walls 108, although other locations within and around the chamber body 102 may be suitable, such as coupled to the stator assembly 118 outside of the process chamber 100. In one embodiment, one or more sensors 116 may be coupled to the stator assembly 118 and are adapted to sense the elevation and/or position of the substrate support 104 (or substrate 140) through the walls 108. In this embodiment, the walls 108 may include a thinner cross-section to facilitate position sensing through the walls 108.

The processing chamber 101 also includes the one or more temperature sensors 117, which may be adapted to sense temperature of the substrate 140 before, during, and after processing. In the embodiment depicted in FIG. 1, the temperature sensors 117 are disposed through the top 112, although other locations within and around the chamber body 102 may be used. The temperature sensors 117 may be optical pyrometers, as an example, pyrometers having fiber optic probes. The temperature sensors 117 may be adapted to couple to the top 112 in a configuration to sense the entire diameter of the substrate, or a portion of the substrate. The temperature sensors 117 may comprise a pattern defining a sensing area substantially equal to the diameter of the substrate, or a sensing area substantially equal to the diameter of the substrate, or a sensing are substantially equal to the radial to the substrate. For example, a plurality of temperature sensors 117 may be coupled to the top 112 in a radial or linear configuration to enable a sensing area across the radius or diameter of the substrate. In one embodiment (not shown), a plurality of temperature sensors 117 may be disposed in a line extending radially from the center of the top 112 to a peripheral portion of the top 112. In this, manner, the radius of the substrate may be monitored by the temperature sensors 117, which enables sensing of the diameter of the substrate during rotation.

The processing chamber 101 (e.g., a RTP chamber) also includes a cooling block 180 adjacent to, coupled to, or formed in the top 112. Generally, the cooling block 180 is spaced apart and opposing the radiant heat source 106. The cooling block 180 comprises one or more coolant channels 184 coupled to an inlet 181A and an outlet 181B. The cooling block 180 comprises one or more coolant channels 184 coupled to an inlet 181A and an outlet 181B. The cooling block 180 may be made of a process resistant material, such as stainless steel, aluminum, a polymer, or a ceramic material. The coolant channels 184 may comprise a spiral pattern, a rectangular pattern, a circular pattern, or combinations thereof and the coolant channels 184 may be formed integrally within the cooling block 180, for example by casting the cooling block 180 and/or fabricating the cooling block 180 from two or more pieces and joining the pieces. Additional or alternatively, the coolant channel 184 may be drilled into the cooling block 180.

As described herein, the processing chamber 101 is adapted to receive a substrate in a “face-up” orientation, wherein the deposit receiving side or face of the substrate is oriented toward the cooling block 180 and the “backside” of the substrate is facing the radiant heat source 106. The “face-up” orientation may allow the energy from the radiant heat source 106 to be absorbed more rapidly by the substrate 140 as the backside of the substrate is typically less reflective than the face of the substrate.

Although the cooling block 180 and radiant heat source 106 is described as being positioned in an upper and lower portion of the interior volume 120, respectively, the position of the cooling block 180 and the radiant heat source 106 may be reversed. For example, the cooling block 180 may be sized and configured to be positioned within the inside diameter of the substrate support 104, and the radiant heat source 106 may be coupled to the top 112. In this arrangement, the window 114 may be disposed between the radiant heat source 106 in the upper portion of the process chamber 100. In one configuration, the window 114 is made of quartz. Although the substrate 140 may absorb heat more readily when the backside is facing the radiant heat source 106, the substrate 140 could be oriented in a face-up orientation or a face down orientation in either configuration.

The inlet 181A and outlet 181B may be coupled to a coolant source 183 by valves and suitable plumbing. The coolant source 183 is in communication with the controller 124 to facilitate control of pressure and/or flow of a fluid disposed there. The fluid may be water, ethylene glycol, nitrogen (N₂), helium (He), or other fluid used as a heat exchange medium.

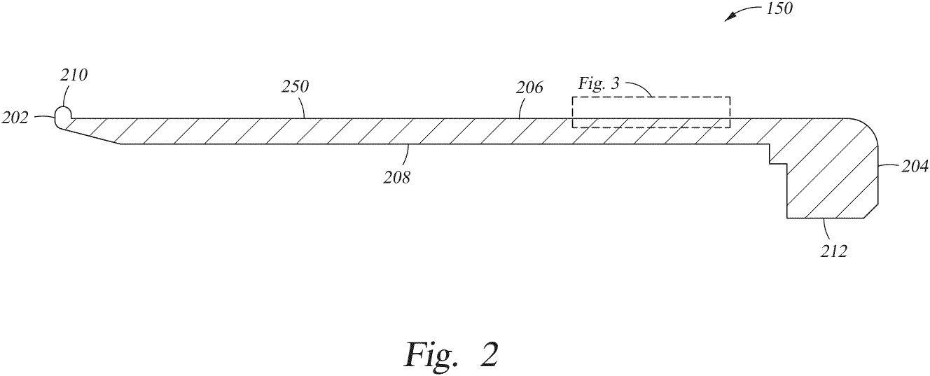

FIG. 2 is a cross section of the support ring 150 according to one embodiment. As seen in FIG. 2, the support ring 150 is typically an annular shape, and includes an inner radius 202, outer radius 204, first side 206 and second side 208. The support ring 150 further includes a first projection 210, and a second projection 212. The support ring 150 is an example of a part that is typically covered in a silicon coating 250. It should be noted that although the coating 250 is referred to herein as a “silicon coating”, the coating 250 can be any coating that is predominately silicon. For example, the silicon coating 250 may comprise silicon oxide (SiO2) as during formation of the silicon coating 250, some oxidation of the silicon may typically occur.

The inner radius 202 has the first projection 210 that extends outwardly from a plane defined by the first side 206. The first projection 210 is used to engage with a complimentary projection on a second support member (e.g., the edge ring of 152 of FIG. 1). The engaged projections are useful to securely position the second support member with the first support member.

The first projection 210 projects from the first side 206 any distance necessary to keep the second support member securely positioned. In one configuration, the projection extends outwardly from the first side between 0.01 in and 0.1 in (for example, 0.04 in). However, the length of the first projection 210 can also be governed by spacing constrains that may exist in alternative embodiments.

In some embodiments, the outer radius 204 includes the second projection 212 that extends outwardly from the second side 208. The second projection 212 is used to engage with a third support member (e.g., the support cylinder of FIG. 1). The second projection 212 can engage with the third support member by extending along an outer surface of the third support member, or by extending along an inner surface of the third support member. In some configurations, the second projection 212 can engage with the third support member by extending beyond the radius of the third support member so that the support ring 150 rests on the third support member. In another configuration, the radius of the second projection 212 is the same as the outer radius 204.

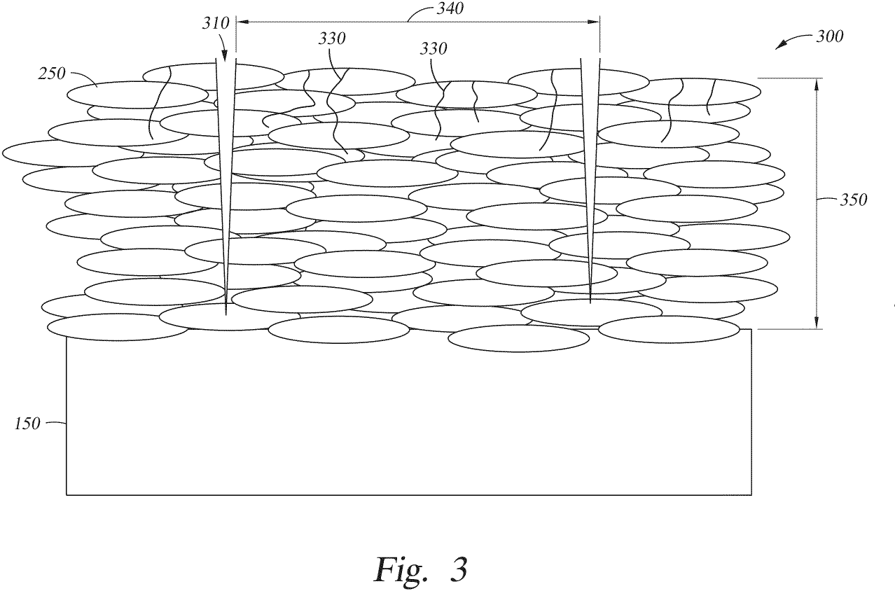

The support ring 150 is coated by the silicon coating 250. The silicon coating 250 is a pre-cracked silicon coating that is a microstructure that enhances the in-plane strain compliance of the coating and reduces coating stress. The silicon coating 250 is further discussed with respect to FIG. 3.

FIG. 3 is a cross-sectional view of the silicon coating 250. FIG. 3 includes the support ring 150, one or more pre-treated vertical cracks 310, and one or more hairline cracks 330 in the silicon coating.

The silicon coating 250 may be applied by an air plasma spray (APS). APS processes spray molten or heat softened material onto a surface to provide a coating. Typically, material in the form of a powder is injected into a high temperature plasma flame, where it is rapidly heated and accelerated to a high velocity. The hot material impacts the surface of the substrate and rapidly cools forming a coating. Upon hitting the surface of the component, each molten droplet forms a pancake-like structure that rapidly solidifies. The pancake-like structures overlap one another as the deposit builds up to a desired thickness. Typically APS processes occur at atmospheric pressures. Plasma spraying has the advantage that it can spray very high melting point materials, such as silicon. Furthermore, plasma spray coatings are generally much denser, stronger, and cleaner than other thermal spray processes. Although APS is referred to herein, it should be noted that the silicon coating 250 may be applied by low pressure plasma spray (LPPS), vacuum plasma spray (VPS), or inert-shrouded APS. These spray techniques are similar to APS except they are performed in a low pressure or inert environments to minimize oxidation of the silicon coating 250.

Although the silicon coating shown in FIG. 3 has some hairline cracks 330, which may be caused by freeze-quenching stresses from splat solidification or thermal expansion mismatch of stresses of repeated thermal cycles in the processing chamber 101, the hairline cracks 330 do not relieve stress in the coating 250. As seen in FIG. 3, the hairline cracks 330 do not penetrate deeply into the coating 250. The shallowness of the hairline cracks 250 thus does not relieve any stress in their current state, and in some case only creates more particles as new hairline cracks form or existing hairline cracks grow during repeated heated and cooling in the processing chamber 101.

As seen in FIG. 3, the silicon coating 250 incorporates large, deep, vertical cracks 310 in the coating 250, which may be formed during formation of the coating 250 or during a post-treatment process. In one embodiment, the large deep vertical cracks exist in the as-sprayed silicon to create the coating 250 by controlling the plasma spray conditions, such as molten particle temperature, particle velocity, torch spray distance, powder feed rate, deposition rate, substrate temperature, substrate rotation, etc. In another embodiment, the cracks 330 are created after the silicon coating 250 is applied. The presence of the deep vertical cracks 310 in the dense silicon coating 250 provide the coating with a higher in-plane elastic compliance, or equivalently, a lower in-plane stiffness. A higher in-plane compliance allows for lower coating stresses due to temperature transients, temperature gradients, and thermal expansion mismatch with the substrate 150 and enables the coating to expand and contract under thermal exposure without the formation of new cracks. Furthermore, higher in-plane compliance allows for the coating to expand and contract without creating new hairline cracks or growing existing hairline cracks. Thus, higher in-plane compliance prevents the release of new and additional particles in RTP processes.

The deep vertical cracks 310 are formed at an average spacing 340 therebetween. In one embodiment, the average spacing 340 between the deep vertical cracks 310 is between 70 µm and 125 µm, such as between 85 µm and 110 µm.

In one embodiment, the thickness 350 of the silicon coating 250 is between 10 µm and 150 µm. In one example the deep cracks 310 extend through at least 40 percent of thickness 350 of the coating 250. For example, the deep cracks 310 extend between 40 percent and 100 percent of the thickness 350 of the coating 250. In one embodiment, the deep cracks 310 extend between 60 percent and 100 percent of the thickness 350 of the coating 250.

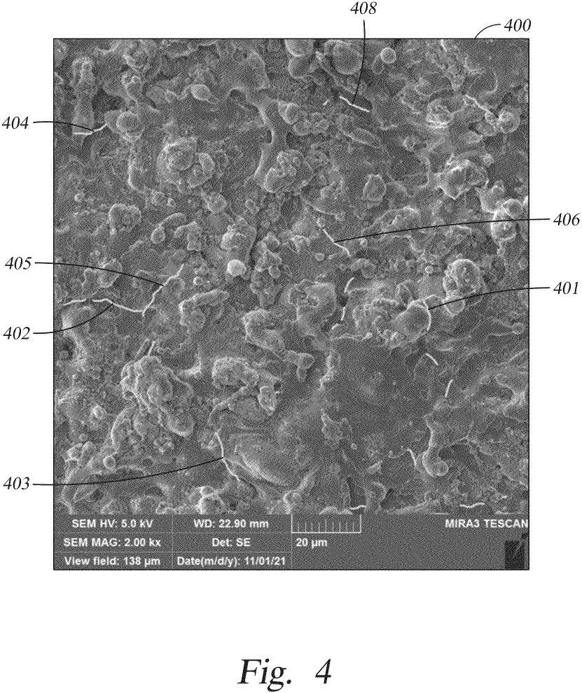

FIG. 4 is a scanning electron microscope (SEM) image of a coating 400, such as the silicon coating 250, with a plurality of deep cracks 401-408. The coating 400 includes between 8 and 20 deep cracks per 100 µm² surface area of the coating 400. In one embodiment, the coating 400 includes between 14 and 20 deep cracks per 100 µm² surface area of the coating 400. Each of the deep cracks 401-408 has an individual crack length. In one embodiment, the each crack length ranges from 1 µm to 200 µm. The total length of the deep cracks 401-408 contained within the coating 400 is an important indication of the strain compliance. In one embodiment, the total length of deep cracks 401-408 includes 8 nm to 20 nm per 1 µm² surface area of coating 400. In another embodiment, the total length of deep cracks 401-408 includes 8 nm to 14 nm per 1 µm² surface area of coating 400. In yet another embodiment, the total length of deep cracks 401-408 includes 14 nm to 20 nm per 1 µm² surface area of coating 400.

While the foregoing is directed to embodiments of the present disclosure, other and future embodiments of the disclosure may be devised without departing from the basic scope thereof, and the scope thereof is determined by the claims that follow.

What is claimed is:

1. A chamber component for a thermal processing chamber, comprising:
a base component having a coating disposed thereon, the coating comprising:
a surface,
a thickness, and
a plurality of cracks extending from the surface of the coating through at least 40 percent of the thickness of the coating.

2. The chamber component of claim 1, wherein the plurality of cracks extend between 60 and 100 percent of the thickness of the coating.

3. The chamber of component of claim 2, wherein the plurality of cracks comprises between 8 and 20 cracks per 100 µm² of surface area.

4. The chamber component of claim 3, wherein the plurality of cracks each has a length between 1 µm and 200 µm.

5. The chamber component of claim 2, wherein the total average length of the plurality of cracks is between 8 nm and 14 nm per 1 µm ² surface area.

6. The chamber component of claim 2, wherein the average spacing between the plurality of cracks is between 70 µm and 125 µm.

7. The chamber component of claim 1, wherein the coating is one of an air plasma sprayed silicon coating, a low pressure plasma sprayed silicon coating, or a vacuum plasma sprayed silicon coating.

8. A support ring for use in a thermal processing chamber, the support ring having a coating disposed thereon, the coating comprising:
a surface,
a thickness, and
a plurality of cracks extending from the surface of the coating through at least 40 percent of the thickness of the coating, wherein the average spacing between the plurality of cracks is between 70 µm and 125 µm.

9. The support ring of claim 10, wherein the plurality of cracks comprises between 8 and 20 cracks per 100 µm² of surface area.

10. The support ring of claim 10, wherein the plurality of cracks each has a length between 1 µm and 200 µm.

11. The support ring of claim 10, wherein the total average length of the plurality of cracks is between 8 nm and 14 nm per 1 µm ² surface area.

12. The support ring of claim 10, wherein the average spacing between the plurality of cracks is between 70 µm and 125 µm.

13. The support ring of claim 10, wherein the plurality of cracks comprises between 12 and 18 cracks per 100 µm² of surface area.

14. A thermal processing chamber, comprising:
a chamber body comprising a base, one or more side walls, and a lid enclosing a processing volume; and
a substrate support comprising a support cylinder, a support ring, and an edge ring disposed within the processing volume, wherein the support ring has a coating disposed thereon, wherein the coating comprises:
a surface,
a thickness, and
a plurality of cracks extending from the surface of the coating through at least 40 percent of the thickness of the coating.

15. The thermal processing chamber of claim 14, wherein the plurality of cracks extend between 60 and 100 percent of the thickness of the coating.

16. The thermal processing chamber of claim 15, wherein the plurality of cracks comprises between 8 and 20 cracks per 100 um² of surface area.

17. The thermal processing chamber of claim 15, wherein the plurality of cracks each has a length between 1 µm and 200 µm.

18. The thermal processing chamber of claim 14, wherein the total average length of the plurality of cracks is between 14 nm and 20 nm per 1 µm ² surface area.

19. The thermal processing chamber of claim 13, wherein the total average length of the plurality of cracks is between 8 nm and 14 nm per 1 µm ² surface area.

20. The thermal processing chamber of claim 13, wherein the average spacing between the plurality of cracks is between 70 µm and 125 µm.
